(19) United States
(12) Patent Application Publication
(10) Pub. No.: US 2012/0152598 A1
(43) Pub. Date: Jun. 21, 2012

(54) WIRING BOARD AND METHOD OF MANUFACTURING THE SAME

(75) Inventors: Erina YAMADA, Komaki-shi (JP); Kazunaga Higo, lida-shi (JP); Hironori Sato, Kasugai-shi (JP)

(73) Assignee: NGK Spark Plug Co., Ltd., Nagoya-shi (JP)

(21) Appl. No.: 13/326,016

(22) Filed: Dec. 14, 2011

(30) Foreign Application Priority Data
Dec. 15, 2010 (JP) 2010-279707
Oct. 14, 2011 (JP) 2011-227310

(51) Int. Cl. H05K 1/09; B23K 31/02; B23K 1/20; H05K 3/10

(52) U.S. Cl. 174/257; 427/97.2; 228/256; 228/246

(57) ABSTRACT

Disclosed is a method for manufacturing a wiring board including a conductor layer, a solder resist layer laminated on the conductor layer, and a conductor post to be electrically connected to a conductor layer which is disposed in a lower portion of a through-hole provided in the solder resist layer, the method including a through-hole boring process of boring the through-hole in the solder resist layer containing a thermosetting resin to expose the conductor layer within the through-hole; a first conductor part forming process of forming a first conductor part composed mainly of copper within the through-hole; and a second conductor part forming process of forming a second conductor part composed mainly of tin, copper, or a solder on the first conductor part, in this order.

### CROSS-REFERENCE TO RELATED APPLICATIONS

The present application claims priority from Japanese Patent Application No. 2010-279707, which was filed on Dec. 15, 2010, and Japanese Patent Application No. 2011-227310, which was filed on Oct. 14, 2011, the disclosure of which is herein incorporated by reference in its entirety.

### BACKGROUND OF THE INVENTION

1. Field of the Invention

The present invention relates to a wiring board and a method of manufacturing the same. In more detail, embodiments of the present invention relate to wiring boards having a conductor post and methods of manufacturing such wiring boards.

2. Description of Related Art

In recent years, as a high-density packaging technique, for example, a C4 (controlled collapse chip connection) method has been adopted. Wiring boards utilized in C4 methods have a surface that is covered by a solder resist layer, and wherein a bump (conductor post) is vertically arranged, in an optionally bored opening in the solder resist layer, and is electronically connected to a conductor layer within the wiring board. For such wiring boards that may be used in C4 methods and which have such a connection with the bump may attain bump pitches as low as 145 μm with the progress of high-density packaging. However, it is expected that high-density packaging will further proceed in the future, and may require narrower bump pitches (for example, 100 μm). These narrower bump pitches require smaller diameter openings to be bored in the solder resist layer. On the other hand, the required height of bumps may be kept constant in the future. Thus, it may be necessary for bumps to have shapes with higher aspect ratios.

Current conventional technologies are described in U.S. Pat. No. 7,216,424. U.S. Pat. No. 6,229,220, and U.S. Patent Publication No. 2005/0029110.

### BRIEF SUMMARY OF THE INVENTION

The formation of bumps having high aspect ratios required for the foregoing high-density packaging is relatively difficult. These general bump forming methods, include a solder printing method and a ball mounting method.

The solder printing method is a method in which a screen mask 22 is used, and a paste solder 30 is printed using a squeegee 21, thereby forming a bump. As illustrated in FIG. 12, in the case where a solder resist layer 13 is thin and a size of a through-hole 131 opened in the solder resist layer 13 is sufficient, the paste solder 30 can usually be printed on a conductor layer 12a.

However, in the case where a solder resist layer 13 is thick, or the diameter of a through-hole 131 formed in the solder resist layer 13 is small, the fabrication of the mask 22 per se is difficult, and it is also difficult to sufficiently ensure its precision. Furthermore, even when a mask 22 can be formed, the diameter of the through-hole 131 opened in the mask 22 is small, which causes problems such as clogging within the mask 22 and the paste solder 30 being hardly printed. Also, as illustrated in FIG. 13, even when the paste solder 30 can be printed, the printed paste solder 30 may have difficulty in coming into contact with the conductor layer 12a.

On the other hand, the ball mounting method is a method in which a previously formed solder ball 40 is joined onto the conductor layer 12a of a leading-out object and is utilized as a bump. As illustrated in FIG. 14, in the case where the solder resist layer 13 is thin and the size of the through-hole 131 opened in the solder resist layer 13 is sufficient, the solder ball 40 can connect with the conductor layer 12a.

However, in the case where the solder resist layer 13 is thick or in the case where the diameter of the through-hole 131 formed in the solder resist layer 13 is small, when the solder ball 40 used has a size that conforms with the diameter of the through-hole 131, a sufficient bump height cannot be ensured. On the other hand, as illustrated in FIG. 15, when the diameter of the solder ball 40 is made large for the purpose of ensuring the height of the bump, the solder balls 40 curvature decreases, so that the solder ball 40 cannot be brought into contact with the conductor layer 12a beneath the solder resist layer 13 (“cissing”). Also, there is a concern that adjoining solder balls 40 connect to each other (“bridge”).

As a substitute method to these conventional general-purpose methods, one may use a method of plating a bump. However, in general, since plating solutions are corrosive to resin layers, the solder resist layer formed by adopting a photolithography method cannot exhibit sufficient corrosion resistance. Also, though it may be necessary to use a frame layer to determine the outline of a bump when plating a bump, it is difficult to sufficiently get the opening that forms in this frame layer to coincide with the opening formed in the solder resist layer.

It is an object of the present invention to provide a wiring board that addresses the above-disclosed long-felt needs, among others.

In view of the foregoing circumstances, the invention has been made, and an object thereof is to provide a wiring board including a conductor post corresponding to the high-density packaging and a method of manufacturing the same. Various aspects of the invention are as follows:

(1) A method for manufacturing a wiring board including a conductor layer, a solder resist layer laminated on the conductor layer, and a conductor post that is electrically connected to a conductor layer which is disposed in a lower portion of a first through-hole provided in the solder resist layer, the method comprising in the following order:

a through-hole boring process of (for) boring the first through-hole in the solder resist layer comprising a thermosetting resin to expose the conductor layer within the first through-hole;

a first conductor part forming process of (for) forming a first conductor part composed mainly of (comprising) copper within the first through-hole; and

a second conductor part forming process of (for) forming a second conductor part composed mainly of (comprising) tin, copper, or a solder on the first conductor part.

(2) The method for manufacturing a wiring board according to (1), further comprising:

an intervening layer forming process of (for) forming an electrically conductive intervening layer comprising nickel and gold on the first conductor part; wherein
the intervening layer forming process occurs before the second conductor part forming process; and
in the second conductor part forming process, the second conductor part is formed on the surface of the intervening layer.

(3) The method for manufacturing a wiring board according to (1) or (2), wherein the second conductor part forming process further comprises:

a printing process of (for) printing a solder paste that forms the second conductor part.

(4) The method for manufacturing a wiring board according to (1) or (2), wherein the second conductor part forming process further comprises:

a ball disposing process of (for) disposing a solder ball that forms the second conductor part; and

a solder ball heating process of (for) heating the solder ball to mold it to form the second conductor part.

(5) The method for manufacturing a wiring board according to (1) or (2), wherein the second conductor part forming process further comprises, in the following order:

a photoresist layer forming process of (for) forming a photoresist layer that covers the surface of a plain substrate, which includes a core substrate, the conductor layer, and the solder resist layer;

a second through-hole boring process of (for) boring in the photoresist layer a second through-hole using a photolithographical method; wherein the second-through hole is in communication with the first through-hole and has a size substantially the same as that of the first through-hole or a diameter larger than that of the first through-hole;

a second conductor part plating process of (for) plating the second conductor part; and

a photoresist layer removing process for removing the photoresist layer, in this order.

(6) The method for manufacturing a wiring board according to (5), wherein the second conductor part forming process further comprises:

a heating process of (for) heating the first conductor part and the second conductor part after the photoresist layer removing process.

(7) A wiring board comprising:

a conductor layer;

a solder resist layer laminated on the conductor layer; and

a conductor post electrically connected to a conductor layer which is disposed in a lower portion of a through-hole provided in the solder resist layer,

wherein the solder resist layer includes a thermosetting resin,

wherein the conductor post includes a first conductor part formed within the through hole and a second conductor part formed on the first conductor part, and

wherein the first conductor part is composed mainly of (comprises) copper, and the second conductor part is composed mainly of (comprises) tin, copper, or a solder.

The manufacturing method of a wiring board of the present invention allows for high-density packaging of conductor posts 16. That is, the wiring boards 10 may have conductor posts 16 having larger aspect ratios (ratio of height to width) than those in the related art. Accordingly, even for conductor posts 16 with small pitches, sufficient height from the surface of the solder resist layer can be attained. Furthermore, high connection reliability can be achieved between the wiring board 10 and a part to be packaged in this wiring board 10 by using a conductor post 16.

In the case where an intervening layer forming process PR4 of forming an electrically conductive intervening layer 17 containing nickel and gold on a first conductor part 181 is included before a second conductor part forming process PR6, and in the second conductor part forming process PR6, a second conductor part 182 is formed on the surface of the intervening layer 17, the joining strength between the first conductor part 181 and the second conductor part 182 can be enhanced.

Regarding the second conductor part forming process PR6, when a printing process PR6-22 of printing a solder paste as the second conductor part 182 is included, advantages from adopting embodiments of the method of the invention can be more effectively obtained.

In the second conductor part forming process PR6, where a ball disposing process PR6-31 of disposing a solder ball 40 as the second conductor part 182 on the first conductor part 181, and a solder ball heating process PR6-32 of heating the solder ball 40 to mold it as the second conductor part 182 are included in this order, advantages from adopting embodiments of the method of the invention can be more effectively obtained.

In the second conductor part forming process PR6, where a photoresist layer forming process PR6-11 of forming a photoresist layer 15 so as to cover the surface of a plain substrate 20 obtained until the preceding processes; a second through-hole boring process PR6-12 of boring, in the photoresist layer 15, a second through-hole 151 which is allowed to communicate with a first through-hole 131 and which has a size substantially the same as that of the first through-hole 131 or a diameter larger than that of the first through-hole 131 by adopting a photolithography method; a second conductor part plating process PR6-13 of plating the second conductor part 182 composed mainly of tin, copper, or a solder within the second through-hole 151; and a photoresist layer removing process PR6-14 of removing the photoresist layer 15 are included in this order, advantages from adopting embodiments of the method of the invention can be more effectively obtained.

In the second conductor part forming process PR6, where plating of the second conductor part 182 composed of tin within the second through-hole 151 and a heating process PR6-16 of heating the first conductor part 181 and the second conductor part 182 after the photoresist layer removing process PR6-14 are included, in the conductor post 16 having an interface between the first conductor part 181 and the second conductor part 182, the metal components constituting the respective parts are diffused into each other. Thus, firm fusion and integration can be obtained, whereby the wiring board 10 having the conductor post 16 can have excellent reliability.

Embodiments of the wiring boards of the present invention are able to allow for high-density packaging of conductor posts 16. That is, the wiring boards 10 may include conductor posts 16 having larger aspect ratios (ratio of height to width) than those in the related art. According to this, even for conductor posts 16 having a small pitch, sufficient height from the surface of the solder resist layer can be attained. Furthermore, connection with high reliability can be achieved between the wiring board 10 and a part to be packaged in this wiring board 10 by using such a conductor post 16. Further, since the solder resist layer 13 may include a thermosetting resin and the first conductor part 181 composed mainly of copper, the thermal expansion coefficient of the solder resist layer 13 and the first conductor part 181 decreases, and therefore a durability of the entire wiring board against stress at the time of mounting a semiconductor chip, such as IC chip, on the wiring board can be improved.

### BRIEF DESCRIPTION OF THE DRAWINGS

Illustrative aspects of the invention will be described in detail with reference to the following figures wherein:

FIG. 1 is a schematic sectional view showing an example of a wiring board obtained by a method of an embodiment of the invention;

FIG. 2 is a schematic process chart showing an outline of a manufacturing method of a wiring board of an embodiment of the invention;

FIG. 3 is a schematic process chart showing an intervening layer forming process (PR4) through a second conductor part forming process (PR6) in a method of an embodiment of the invention;

FIG. 4 is a schematic process chart continuing from FIG. 3;

FIG. 5 is a schematic process chart showing an intervening layer forming process (PR4) through a second conductor part forming process (PR6) in a method of an embodiment of the invention;

FIG. 6 is a schematic process chart continuing from FIG. 5;

FIG. 7 is a schematic process chart showing an intervening layer forming process (PR4) through a second conductor part forming process (PR6) in a method of an embodiment of the invention;

FIG. 8 is a schematic process chart continuing from FIG. 7;

FIG. 9 is a schematic process chart showing an intervening layer forming process (PR4) through a second conductor part forming process (PR6) in a method of an embodiment of the invention;

FIG. 10 is a schematic process chart showing another method, from a first conductor part forming process (PR3) through a second conductor part forming process (PR6) of an embodiment of the invention;

FIG. 11 is a schematic process chart showing another method from a first conductor part forming process (PR3) through a second conductor part forming process (PR6), of an embodiment of the invention;

FIG. 12 is a schematic view showing a known manufacturing method;

FIG. 13 is a schematic view showing a potential problem in the known manufacturing method;

FIG. 14 is another explanatory view showing another known manufacturing method;

FIG. 15 is another view showing a potential problem in the other known manufacturing method; and

FIG. 16 is a schematic sectional view showing an embodiment of the wiring board.

### DETAILED DESCRIPTION OF EXEMPLARY EMBODIMENTS OF THE INVENTION

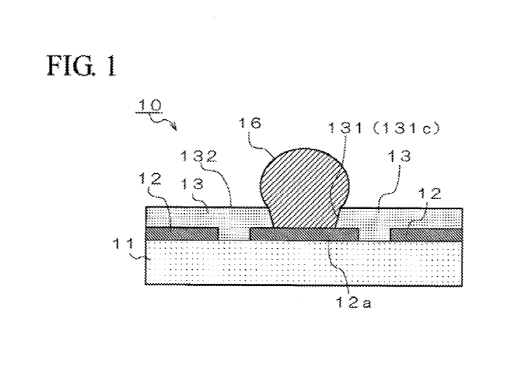

An embodiment of the present invention is hereunder described in detail by reference to FIGS. 1 to 11 and 16.

[1] Wiring Board:

A wiring board 10 according to the present invention and a wiring board 10 which is obtained by the manufacturing method of the invention comprises a conductor layer 12, a solder resist layer 13, and a conductor post 16.

The conductor layer 12 is a layer functioning as a conductor circuit or the like in the wiring board 10. The conductor layer 12 may be composed of a series (namely, a continuous single sheet) of conductors, or may be composed of a plurality of conductors arranged within the same plane. Also, among the conductor layers 12, the conductor layer which is disposed in a lower portion of a through-hole 131 bored in the solder resist layer 13 is a conductor layer 12a. This conductor layer 12a may be an independent single conductor within the conductor layer 12, or may be a part of continuous conductors. Also, the shape or the like of the conductor layer 12 is not particularly limited. Also, though the material of the conductor layer 12 is not particularly limited, it is preferably copper, a copper alloy, aluminum, an aluminum alloy, or the like. In certain embodiments, copper is used preferably.

The solder resist layer 13 is a layer that may contain a thermosetting resin. This solder resist layer 13 is a layer which is laminated on the conductor layer 12. In general, the solder resist layer 13 functions as a layer for preventing attachment of a solder to an unintended site during a reflow process, which is utilized during packaging a part in a wiring board. Other layer such as an insulating layer may be allowed to intervene between this solder resist layer 13 and the conductor layer 12.

The conductor post 16 is a conductor which is electrically connected to the conductor layer 12a disposed in a lower portion of the through-hole 131 which is provided in the solder resist layer 13. Then, the conductor post 16 functions as a conductor for connecting the conductor layer 12a to the outside of the resist layer 13.

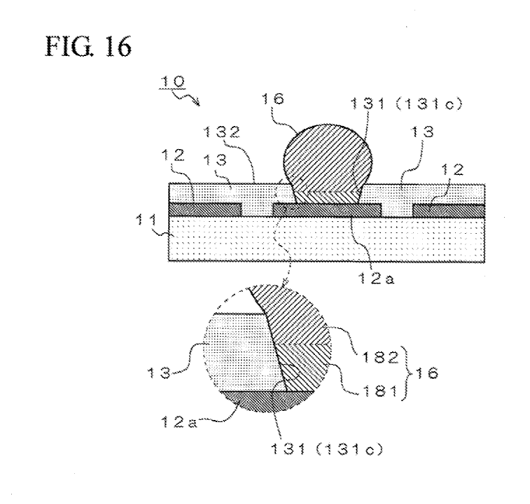

Also, in general, as illustrated in FIG. 1 and FIG. 16, the conductor post 16 has a shape that fills up the inside of the through-hole 131 and is also projected outside the solder resist layer 13. In other words, the conductor post 16 being projected outside the solder resist layer 13 means that the conductor post 16 is projected toward the outside from the outer surface of the solder resist layer 13. According to this, the conductor post 16 is configured such that it is projected from the surface of the wiring board 10 and is able to package a part therein.

Though a shape (inclusive of a planar shape and a side surface shape) of the portion of the conductor post 16 that is projected outside the solder resist layer is not particularly limited, for example, the planar shape can be a circular shape, a quadrilateral shape, or the like. Also, the side surface shape (shape of side section) can be a substantially circular shape, a semicircular shape, a quadrilateral shape, or the like.

As shown in FIG. 16, the conductor post 16 includes a first conductor part 181 formed within a through hole 131 (first through hole) formed through the solder resist layer 13, and a second conductor part 182 formed on the first conductor part. Since the first conductor part 181 is provided, a ratio (depth/opening diameter) of a depth of the through hole 131 to an opening diameter of the through hole 131 can be made small such that the through hole 131 can be closed by filler. Therefore, the second conductor part 182 can be electrically connected to the conductor layer 12a through the first conductor part 181.

The first conductor part 181 comprises mainly of copper, and the second conductor part 182 comprises mainly of tin, copper, or a solder. The first conductor part 181 composed mainly of copper will be described later in the description of “first conductor part forming process PR3”. The second conductor part 182 composed mainly of tin, copper, or a solder will be described later in the description of “second conductor part forming process PR6”.

Further, the conductor post 16 may be provided with an alloy layer 165 interposed between the first conductor part 181 and the second conductor part 182. If the alloy layer 165 is formed using an intervening layer 17, as described later, the alloy layer 165 can be formed by alloying the intervening layer 17 between the first conductor part 181 and the second conductor part 182 (diffusing the component of the intervening layer 17).

Furthermore, embodiments of the wiring board 10 according to the invention and the wiring board 10 which is obtained by the embodied methods of the invention can be provided with other parts than those described above. Examples of other parts include a core substrate, an insulating layer, and an interior pail.

Of these, the core substrate comprises an insulating material that is generally a plate-shaped material. Also, the core substrate can form a central part, in a thickness direction, of the wiring board 10. As the insulating material constituting the core substrate, an insulating resin is preferable, and examples thereof include epoxy resins and bismaleimide-triazine resins. Also, a reinforcing material (for example, reinforcing fibers such as glass fibers), a filler (for example, various fillers such as silica and alumina), and the like may be contained in the core substrate. That is, for example, fiber reinforced resin plates such as a glass fiber reinforced epoxy resin plates or the like, heat resistant resin plates such as a bismaleimide-triazine resin plate, and the like can be used as the core substrate. Also, this core substrate may be composed of a plurality of layers, and furthermore, it may have a conductor layer (inner layer pattern) in the inside thereof. Also, the insulating layer is a layer having a function to insulate a space between the conductor layers laminated on the core substrate. This insulating layer can comprise the same insulating material as the insulating material that comprises the core substrate.

Furthermore, in the case where embodiments of the wiring board 10 according to the invention and the wiring board 10 which is obtained by the embodied methods of the invention include an accommodating part in the inside thereof, the wiring board 10 is able to have an interior part within the accommodating part.

The planar shape of the accommodating part is not particularly limited, and for example, it may be a substantially quadrilateral shape (inclusive of a quadrilateral and a quadrilateral whose corners are chamfered), or it may be a substantially circular shape (inclusive of a true circular shape and an elliptical shape), or the like. Also, examples of the interior part include a capacitor, an inductor, a filter, a resistor, and a transistor. These materials may be used singly or in combination with two or more kinds thereof. Of these, a capacitor is preferable, and in particular, a laminated ceramic capacitor is suitable. Furthermore, a filling part having an insulating material that functions to relieve thermal expansion coefficient characteristics between the interior part and the core substrate can be included in a gap between the interior part internally installed within the accommodating part and the accommodating part. In general, the filling part is composed of (comprises) a resin such as epoxy resins, silicone resins, polyimide resins, bismaleimide-triazine resins, urethane resins, and phenol resins, or it may be composed of (comprise) a mixture of such a resin and an inorganic filler such as ceramics with low thermal expansion (for example, silica, alumina, etc.), dielectric ceramics (for example, barium titanate, strontium titanate, lead titanate, etc.), heat-resistant ceramics (for example, alumina nitride, boron nitride, silicon carbide, silicon nitride, etc.), and glasses (for example, borosilicate based glass, etc.).

[2] Method of Manufacturing Wiring Board:

An embodiment of a method for manufacturing a wiring board according to the invention comprises a through-hole boring process PR2, a first conductor part forming process PR3, and a second conductor part forming process PR6, in this order.

The foregoing “through-hole boring process (PR2)” is a process of boring a through-hole (first through-hole) 131 in the solder resist layer 13 containing a thermosetting resin. By boring this through-hole 131, the conductor layer 12a is exposed within the through-hole 131 (at the bottom of the through-hole 131) from a lower part of the solder resist layer 13. Then, the conductor layer 12a is connected to the conductor post 16 via the bored through-hole 131, and the conductor layer 12a is electrically connected to the outside of the solder resist layer 13.

Though the thickness of this solder resist layer 13 is not particularly limited, it is preferably 1 μM or more and not more than 100 μm. When the thickness of the solder resist layer 13 falls within this range, by adopting the configuration of the invention, the foregoing effects may be obtainable. The thickness of this solder resist layer 13 is more preferably 5 μm or more and not more than 50 μm, and especially preferably 10 μm or more and not more than 40 μm.

Also, the solder resist layer 13 contains (comprises) a thermosetting resin (an uncured state, a semi-cured state, and/or a cured state). When the solder resist layer 13 contains a thermosetting resin, it is possible to impart resistance to a plating solution (in particular, alkali resistance) while preventing unnecessary attachment of a solder in the reflow process which is a process utilized during packaging a part in the wiring board 10. According to this, it becomes possible to form at least one of an electroless plating and an electroplating on a surface 12ap of the conductor layer 12, and in particular, on a surface 13p of the solder resist layer 13.

Furthermore, the solder resist layer 13 containing (comprising) the thermosetting resin can have superior anti-cracking performance and superior anti-migrationing performance as compared with solder resist layers containing only a photosensitive resin. Further, as described later, in the case that the Sn (tin) is used as a conductive material, if the wiring board provided with the solder resist layer is formed only of a photosensitive resin, stress after mounting the semiconductor chip is likely increased. This is because the thermal expansion coefficient of the photosensitive resin is higher than that of the semiconductor chip (thermal expansion coefficient of the photosensitive resin: 50-70 ppm/° C., and thermal expansion coefficient of the semiconductor chip: about 4 ppm/° C.). Contrary to this, by containing the thermosetting resin with a relatively small thermal expansion coefficient in the solder resist layer, the difference in thermal expansion coefficients between the solder resist layer and the semiconductor chip can be decreased, thereby decreasing the stress of the wiring board on which the semiconductor chip is mounted.

Though the kind of the thermosetting resin constituting the solder resist layer 13 is not particularly limited, examples thereof include epoxy resins, polyimide resins, phenol resins, bismaleimide-triazine resins, cyanate resins, and polyamide resins. Of these, epoxy resins are especially preferable. Examples of the epoxy resins include novolak type epoxy resins such as phenol novolak types and cresol novolak types; and dicyclopentadiene-modified alicyclic epoxy resins. These resins may be used singly or in combination with two or more kinds thereof.

Though the amount of thermosetting resin which is contained in the solder resist layer 13 is not particularly limited, in general, the thermosetting resin is contained in the largest volumetric amount in the organic material that constitutes the solder resist layer 13. That is, the thermosetting resin is a main component in the organic material constituting the solder resist layer 13. More specifically, when the amount of the organic material constituting the solder resist layer 13 is defined as 100% by volume, it is preferable that the thermosetting resin be contained in an amount exceeding 50% by volume to 100% by volume. Though the content of the thermosetting resin in the organic material constituting the solder resist layer 13 is not particularly limited, it can be preferably more than 50% by volume and not more than 100% by volume, and more preferably 80% by volume or more and not more than 100% by volume. Also, examples of organic materials other than thermosetting resin which comprise the solder resist layer 13 include rubbers and thermoplastic resins.

Also, in addition to the organic material, which includes the foregoing thermosetting resin, a filler (for example, various inorganic fillers, e.g., silica, alumina, etc.; in general, an inorganic material) or the like may be contained in the solder resist layer. In the case where a filler is contained, when the whole of the solder resist layer 13 is defined as 100% by mass, the content of the filler is not more than 70% by mass.

In the through-hole boring process PR2, the through-hole 131 may be bored by any method. That is, for example, the first through-hole 131 may be formed by adopting a photolithographical method; the first through-hole 131 may be formed by adopting a laser boring method; or the first through-hole 131 may be formed by any combination of these methods.

Also, the through-hole 131 to be bored may penetrate through the solder resist layer 13, and its shape is not particularly limited. For example, a planar shape of the through-hole 131 may be a circular shape, a polygonal shape such as a quadrilateral shape, or any other shape, with circular shapes being preferable. Also, though the size of this through-hole 131 is not particularly limited, in general, it is sized such that only a part of the conductor layer 12a is exposed (namely, it is preferable that the whole conductor layer 12a not be exposed).

Furthermore, in general, the size of the opening of the through-hole 131 is not particularly limited. However, in the case where the planar shape of the through-hole 131 is a circular shape, it is preferable that its diameter be 10 μm or more and not more than 100 μm, and its depth (thickness of the solder resist layer 13) be 1 μm or more and not more than 100 μm. In wiring boards 10 having such a through-hole 131, the advantageous effects of the invention are more easily obtainable. It is more preferable that this diameter be 30 μm or more and not more than 150 μm, and the depth be 5 μm or more and not more than 50 μm; and it is especially preferable that the diameter be 40 μm or more and not more than 100 μm, and the depth be 5 μm or more and not more than 40 μm.

The foregoing “first conductor part forming process (PR3)” is a process of forming a first conductor part 181, composed mainly of copper, within the through-hole 131 in which the conductor layer 12a is exposed due to boring of the through-hole (e.g., first through-hole) 131.

By forming this first conductor part 181, it is possible to reduce the ratio (depth/opening diameter) of the depth of a through hole 131 opened in the solder resist layer 13 to the diameter of the opening, or to fill and plug the through hole 131. According to this, a second conductor part 182 can be electrically connected to the conductor layer 12a via the first conductor part 181. That is, it becomes possible to connect the conductor post 16 and the conductor layer 12a with ease.

The first conductor part 181 may be formed by any method. That is, for example, the first conductor part 181 may be formed by an electroless plating method, or may be formed by a method that involves filling with a conductor paste.

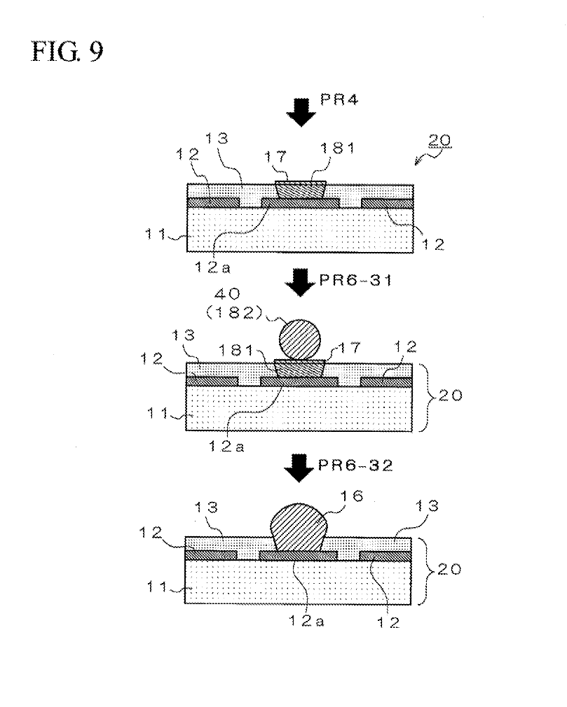

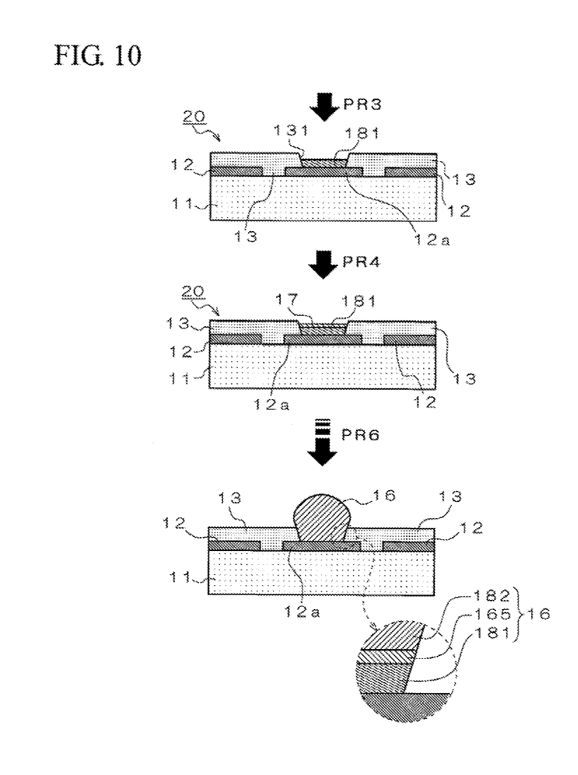

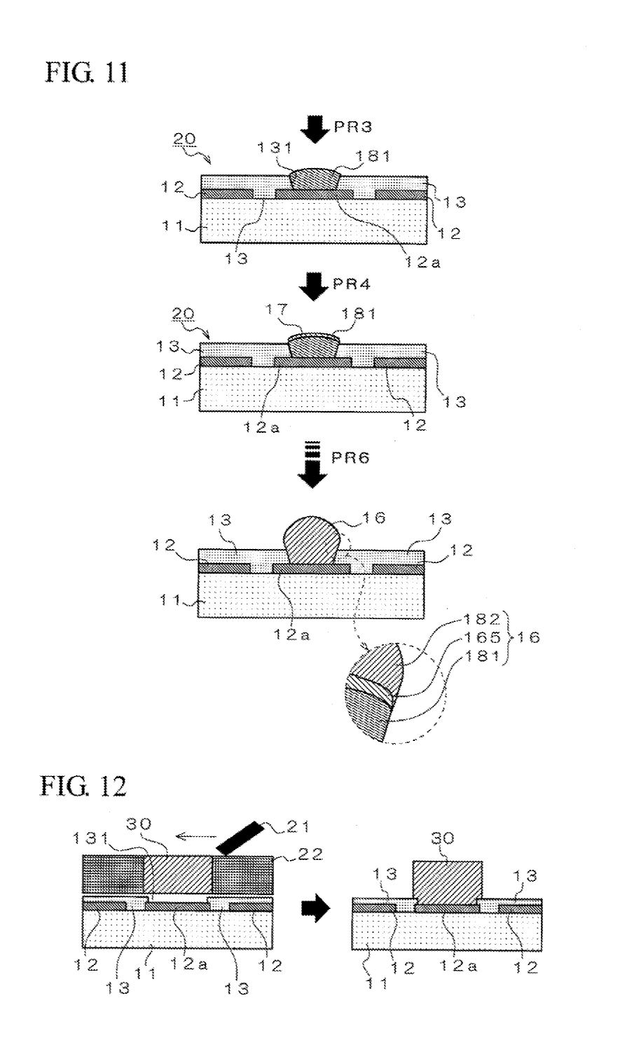

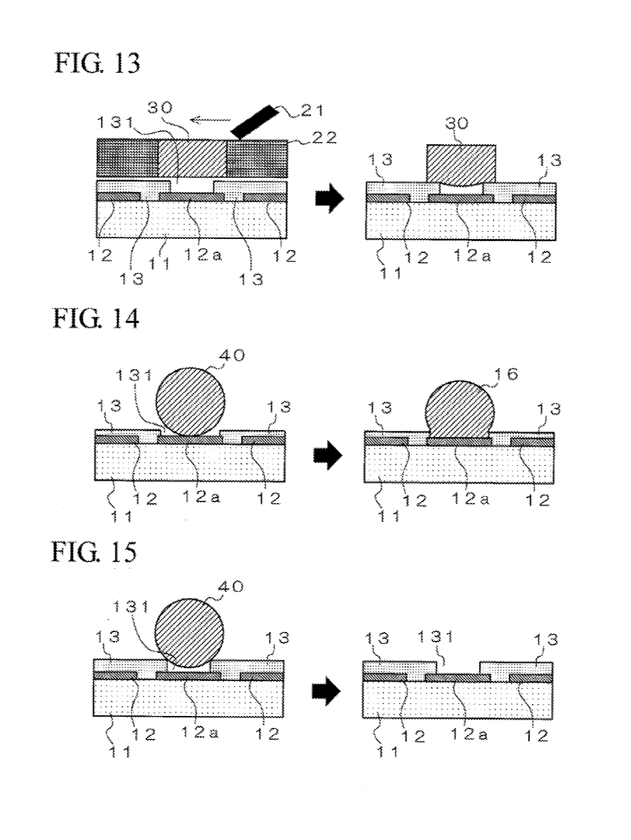

Also, this first conductor part 181 may be formed to any dimension. For example, as illustrated in FIG. 10, the first conductor part 181 may be formed such that only a part of the through-hole 131 is filled (FIG. 10), the first conductor part 181 may be formed such that the whole of the through hole 131 is filled (FIG. 9), the first conductor part 181 may be formed such that not only is the whole of the through hole 131 is filled, but it overhangs outside the solder resist layer 13 (namely, it is projected outside) from the through-hole 131 (FIG. 11). Incidentally, when an intervening layer 17 is included as described later, it is preferable that the thickness of the first conductor part 181 in a depth direction be larger than the thickness of the intervening layer 17. In such cases, the first conductor part 181 may have more technical significe.

The first conductor part 181 comprises a material composed mainly of copper. Since the first conductor part 181 is composed mainly of the copper, which has low thermal expansion, the overall ratio of copper in the conductor post 16 is increased, thereby decreasing the thermal expansion coefficient of the entire conductor post 16 (as compared with conductor posts 16 composed only of Sn, which has a thermal expansion coefficient of 23.5 ppm/° C., for example).

A first conductor part 181 comprising mainly copper means that, in the case where the whole of the first conductor part 181 is defined as 100% by mass, the content of Cu is 95% by mass or more (preferably 97% by mass or more, up to 100% by mass). Also, the first conductor part 181 may contain elements other than Cu, such as Sn. These metal elements may be contained singly or in combination with two or more kinds thereof.

Incidentally, the components contained in the first conductor part 181 may be perceived through observation by SPMA with a magnification of 1,000 times or more.

The “second conductor part forming process (PR6)” is a process of forming the second conductor part 182 comprising mainly tin, copper, or a solder on the first conductor part 181.

The second conductor part 182 comprises tin, copper, or a solder. A second conductor part 182 comprising mainly tin means that, in the case where the whole of the second conductor part 182 is defined as 100% by mass, the content of Sn is 95% by mass or more (preferably 97% by mass or more, up to 100% by mass). Also, in the case where the second conductor part 182 contains metal elements other than Sn, examples of such other metal elements include Cu, Ag, Zn, In, Bi, Sb, and Pb. These metal elements may be contained singly or in combination with two or more kinds thereof.

Also, a second conductor part 182 comprising mainly of copper means that, in the case where the whole of the second conductor part 182 is defined as 100% by mass, the content of Cu is 95% by mass or more (preferably 97% by mass or more up to 100% by mass). Also, in the case where the second conductor part 182 contains metal elements other than Cu, examples of such other metal elements include Sn. These metal elements may be contained singly or in combination with two or more kinds thereof.

Furthermore, a second conductor part 182 is comprising mainly a solder means that, in the case where the whole of the second conductor part 182 is defined as 100% by mass, a total content of two or more members selected from the group consisting of Sn, Ag, Cu, Zn, Al, Ni, Ge, Bi, In, Pb, and Au is 95% by mass or more (preferably 97% by mass or more up to 100% by mass). More specifically, examples of the solder constituting the second conductor part 182 include an SnPb solder, an SnAgCu solder, an SnBi solder, an SnZnBi solder, an SnCu solder, an SnAgInBi solder, an SnZnAl solder, and an SnCuNiGe solder.

Incidentally, the components contained in the second conductor part 182 may be perceived through observation by EPMA with a magnification of 1,000 times or more.

Also, the first conductor part 181 and the second conductor part 182 may comprise the same or different materials.

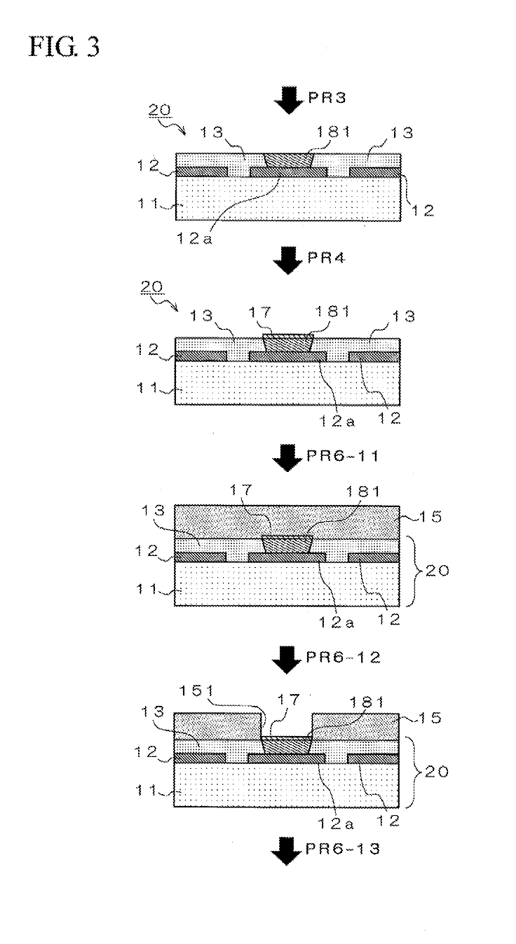

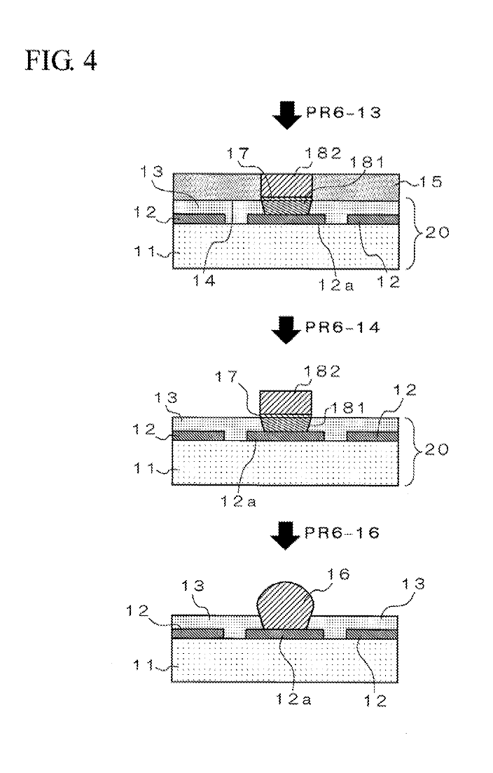

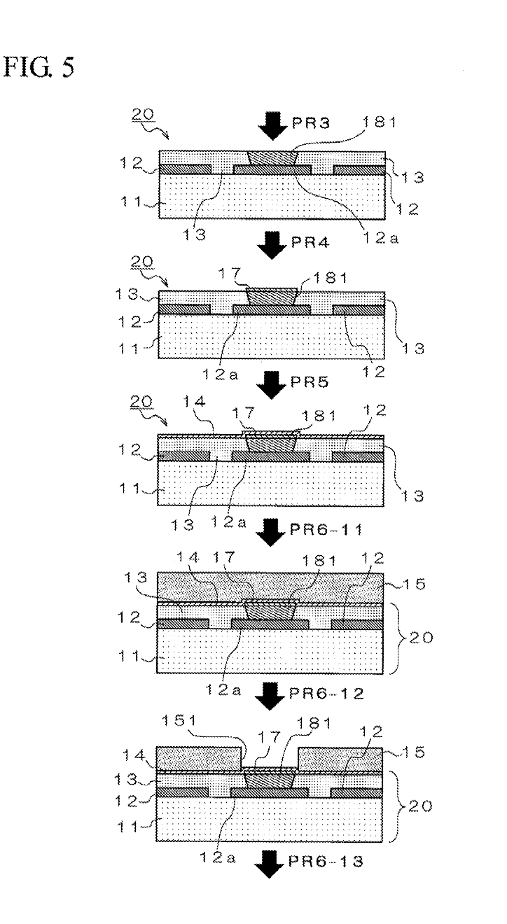

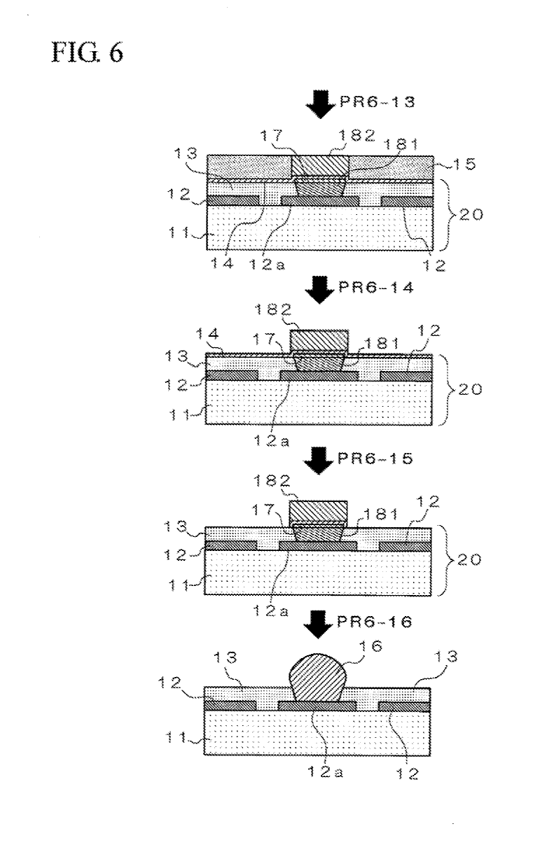

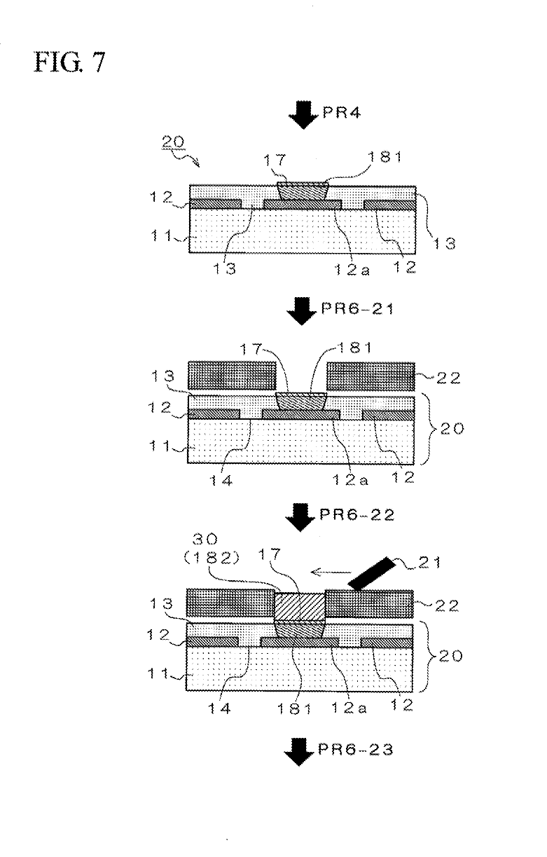

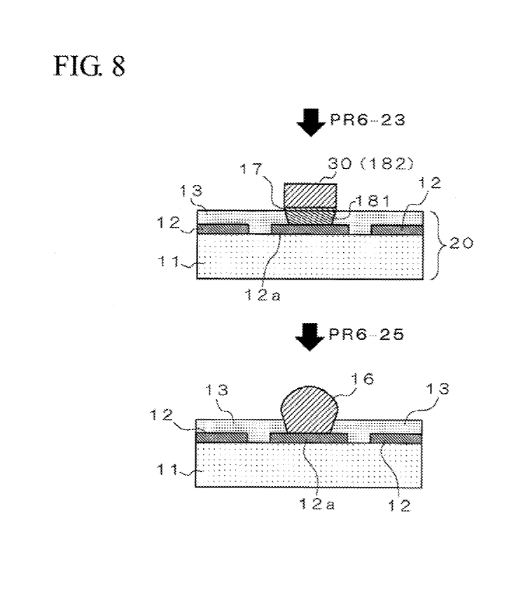

Similarly to the first conductor part 181, the second conductor part 182 may be formed by any method. That is, examples thereof include (1) a method of forming the second conductor part 182 by adopting a photolithography method, as illustrated in FIGS. 3 to 4 {(PR6-11) to (PR6-16)} and FIGS. 5 to 6 {(PR6-11) to (PR6-16)}; (2) a method of forming the second conductor part 182 by adopting a screen printing method, as illustrated in FIGS. 7 and 8; and (3) a method of forming the second conductor part 182 by using a solder ball 40, as illustrated in FIG. 9. These methods are hereunder described.

(1) Formation of the second conductor part 182 by adopting a photolithography method (see FIGS. 3 to 4 and FIGS. 5 to 6): The second conductor part forming process PR6 of forming the second conductor part 182 by adopting a photolithography method includes:

a photoresist layer forming process PR6-11 of forming a photoresist layer 15 so as to cover the surface of the plain substrate 20 obtained in preceding processes;

a second through-hole boring PR6-12 process, in the photoresist layer 15, to form a second through-hole 151 which is allowed to communicate with the first through-hole 131 and which has a size substantially the same as that of the first through-hole 131 or a diameter larger than that of the first through-hole 131 by adopting a photolithography method;

a second conductor part plating process PR6-13 of plating the second conductor part 182 composed mainly of tin, copper, or a solder within the both holes of the first through-hole 131 and the second through-hole 151; and

a photoresist layer removing process PR6-14 of removing the photoresist layer 15, in this order.

The foregoing “photoresist layer forming process (PR6-11)” is a process of forming the photoresist layer 15 so as to cover the plain substrate 20 obtained in preceding processes. That is, the photoresist layer forming process (PR6-11) is a process of performing any one of (1) a process of forming the photoresist layer 15 on the plain substrate 20 having the first conductor part 181 formed thereon via the first conductor part forming process PR3; (2) a process of forming the photoresist layer 15 on the plain substrate 20 having an intervening layer 17 formed thereon via an intervening layer forming process PR4, as described later (see FIGS. 3); and (3) a process of forming the photoresist layer 15 on the plain substrate 20 having an electroless plated layer 14 (electroless plated layer 14 to be utilized as a current-carrying electrode during electroless plating of the second conductor part 182) formed thereon via an electroless plated layer forming process PR5, as described later (see FIG. 5).

Methods of forming the photoresist layer 15 are not particularly limited, and the photoresist layer 15 can be obtained by (A) a method in which a liquid photoresist composition is coated on the solder resist layer 13, followed by drying, curing (semi-curing), or the like, if desired. Furthermore, the photoresist layer 15 can be obtained by (B) a method in which a dry film serving as the photoresist layer 15 is stuck on the solder resist layer 13, followed by drying, curing (semi-curing), or the like, if desired. In the case of utilizing the foregoing method (A), the liquid photoresist composition can be coated on the solder resist layer 13 by an appropriate coating method such as spin coating, cast coating, and roll coating. On the other hand, in the case of utilizing the foregoing method (B), the dry film can be brought into intimate contact with the solder resist layer 13 upon being pressed. In such cases, though pressing may be performed by using a batch type press, the pressing can be performed while allowing the dry film to pass through a manufacturing line, and therefore, a roller type press or the like can be used.

Though the thickness of the photoresist layer 15 is not particularly limited, it is preferably 1 μm or more and not more than 500 μm. In the case where the thickness of the photoresist layer 15 falls within this range, the second conductor part 182 can be formed upon being sufficiently projected outside the solder resist layer 13, and satisfactory connection to the outside via the conductor post 16 can be obtained. The thickness of this photoresist layer 15 is more preferably 5 μm or more and not more than 300 μm, and especially preferably 10 μm or more and not more than 100 μm.

The foregoing “second through-hole boring process (PR6-12)” is a process of boring, in the photoresist layer 15, the second through-hole 151, which is allowed to communicate with the first through-hole 131 and which has a size that is substantially the same as that of the first through-hole 131 or a diameter larger than that of the first through-hole 131, using a photolithography method. The second through-hole 151 is a through-hole which penetrates the back and front sides of the photoresist layer 15, and it is bored from the surface side of the photoresist layer 15 and penetrates to the side of the solder resist layer 13. This second through-hole 151 serves as a mold for forming the second conductor part 182. Incidentally, when the first conductor part 181 is formed so as to project outside the solder resist layer 13, as illustrated in FIG. 11, or in the case where an intervening layer 17 is formed, there may be a state in which the first conductor part 181 or the intervening layer 17 is disposed within the second through-hole 151.

Also, this second through-hole 151 has a size that is substantially the same as that of the first through-hole 131 or a diameter that is larger than that of the first through-hole 131. A second through-hole 151 having a size substantially the same as that of the first through-hole 131 means that, defining a diameter of the first through-hole 131 as L131 and a diameter of the second through-hole 151 as L151, there is a relation of 0.5≦L151/L131≦1. On the other hand, in the case where the second through-hole 151 has a diameter larger than that of the first through-hole 131, a relation of 1<L151/L131≦5 is preferable, a relation of 1<L151/L131≦1.5 is more preferable, and a relation of 1<L151/L131≦1.2 is especially preferable. Incidentally, the diameter L131 is an average length of four diameters that divide the opened surface of the first through-hole 131 into eight equal parts. Similarly, diameter L151 is the average length of four diameters that divide the opened surface of the second through-hole 151 into eight equal parts.

The foregoing “second conductor plating process (PR6-13)” is a process of plating the second conductor part 182, composed mainly of tin, copper, or a solder, within the both holes of the first through-hole 131 and the second through-hole 151. However, as illustrated in FIGS. 3 and 11, in the case where the first through-hole 131 is filled up by the first conductor part 181, process PR6-13 is a process of plating the second conductor part 182 composed mainly of tin, copper, or a solder within the second through-hole 151. That is, the process PR6-13 is a process of forming the second conductor part 182 on the first conductor part 181 (the formation may be performed via the intervening layer 17 or the electroless plated layer 14, as described later).

In process PR6-13, any plating means may be adopted. That is, for example, the second conductor part 182 may be formed by means of electroless plating, or the second conductor part 182 may be formed by means of electroplating.

The foregoing “photoresist layer removing process (PR6-14)” is a process of removing the photoresist layer 15. That is, the process PR6-14 is a process of removing the photoresist layer 15 and exposing the second conductor part 182 onto the substrate. The removal of the photoresist layer 15 may be performed by any method. For example, the photoresist layer 15 may be burnt down (reduced to ashes) by applying a laser, heat, or the like, or it may be dissolved and removed by using a solvent or the like. In particular, in the case of using a positive working photoresist as the photoresist, the photoresist layer 15 can be removed simply and easily with a solvent.

Furthermore, in this second conductor part forming process PR6, as illustrated in FIG. 6, the electroless plated layer 14 may appear in the lower part of the photoresist layer. Thus, an electroless plated layer removing process PR6-15 to remove any Unnecessary part of the electroless plated layer 14 can be included. This process can be performed by any method, such as etching.

Also, the second conductor part forming process PR6 may comprise, as illustrated in FIGS. 4 and 6, a heating process PR6-16 of heating (reflowing) the conductor parts (the first conductor part 181, the intervening layer 17, the electroless plated layer 14, the second conductor part 182, and so on) formed in the preceding processes to achieve integration. That is, the heating process PR6-16 of heating the first conductor part 181 and the second conductor part 182 can be included. According to this process PR6-16, in the conductor post 16 at the interface between the first conductor part 181 and the second conductor part 182, the metal components that constitute the respective parts may be diffused into each other, firmly fusing and integrating the parts. Furthermore, by this heating, each of the conductor parts are moderately dissolved, and in particular, the dissolved second conductor part 182 can be modified to correct any contortion in shape due to surface tension by rounding the second conductor part 182 (see FIGS. 4 and 6). Moreover, the position of the whole of the conductor post 16 can be corrected through a self-alignment effect so as to allow an axial center thereof to coincide with the conductor layer 12a. Accordingly, a wiring board 10 having a conductor post 16 with excellent reliability can be obtained. The foregoing effects due to this heating process PR6-16 are effective especially where the second conductor part 182 is formed mainly of tin.

The heating conditions (reflowing conditions) during the heating process PR6-16 or the like are not particularly limited. However, in the case where the second conductor part is formed mainly of tin or a solder, it is preferable to perform heating at a temperature of 100° C. or higher and not higher than 400° C. in atmospheric conditions. When the heating temperature falls within this range, the foregoing self-alignment effect can also be obtained. This temperature is more preferably 150° C. or higher and not higher than 300° C., and especially preferably 180° C. or higher and not higher, than 260° C. In particular, a maximum temperature during reflowing is preferably at least 30° C. higher than a melting point of a material (e.g., Sn or a solder) constituting the second conductor part 182 (melting point of the second conductor part 182 per se).

Also, in the case where the second conductor part plating process PR6-13 is performed by electroplating, as illustrated in FIG. 5, an electroless plated layer forming process PR5 can be included. That is, process PR5 is a process of performing electroless plating on the surface of a plain substrate 20, which is obtained prior to performing process PR5, to form an electroless plated layer 14. The electroless plated layer 14 obtained in this process is utilized as a current-carrying electrode during the formation of the second conductor part 182 by an electroplating method.

The material constituting this electroless plated layer 14 is not particularly limited so long as it is electrically conductive. However, similarly to the material constituting the foregoing second conductor part 182, the material constituting this electroless plated layer 14 is preferably composed mainly of tin or copper. Also, as illustrated in FIG. 6, after removing the photoresist layer 15 in the photoresist layer removing process PR6-14, there generally follows an electroless plated layer removing process PR6-15 that removes unnecessary parts of the electroless plated layer 14 exposed from a lower part of the photoresist layer 15. The electroless plated layer removing process PR6-15 is usually performed by means of etching.

(2) Formation of the second conductor part 182 using a screen printing method (see FIGS. 7 and 8): The second conductor part forming process PR6 of forming the second conductor part 182 with a screen printing method includes a printing process for printing a solder paste 30, which forms the second conductor part 182. More specifically, as illustrated in FIGS. 7 and 8, there can be included a mask disposing process PR6-21 of disposing a screen mask 22; a solder paste printing process PR6-22 of printing the solder paste 30 on the first conductor part 181 (printing may be performed via the intervening layer 17 as described later) by utilizing the screen mask 22; and subsequent to the solder paste printing process PR6-22, a mask removing process PR6-23 of removing the screen mask 22.

Also, in this second conductor part forming process PR6, as illustrated in FIG. 8, the conductors formed in the preceding processes can be integrated upon heating (reflowing). That is, one can include a heating process PR6-25 of heating the first conductor part 181 and the second conductor part 182 (solder paste 30). According to this process PR6-25, the conductor post 16 in which the metal components that constitute each of the first conductor part 181 and the second conductor part 182 are diffused into each other at the interface therebetween, firmly fusing and integrating the parts. Furthermore, according to this heating, each of the conductor parts is moderately dissolved, and in particular, the contortion of the dissolved second conductor part's 182 shape due to surface tension can be corrected by rounding it. Moreover, the position of the whole conductor post 16 can be corrected through a self-alignment effect so as to allow an axial center thereof to coincide with the conductor layer 12a. According to these actions, the wiring board 10 may have a conductor post 16 with increased reliability. The foregoing effects due to this heating process PR6-25 are especially effective where the second conductor part 182 is formed mainly of tin.

Though the heating conditions (reflowing conditions) in the heating process PR6-25 or the like are not particularly limited, the conditions in the foregoing formation of the second conductor part 182 by a photolithography method can be applied.

(3) Formation of the second conductor part 182 using a solder ball (see FIG. 9): The second conductor forming process PR6 of forming the second conductor part 182 by using a solder ball can include a ball disposing process PR6-31 of disposing a solder ball 40 as the second conductor part on the first conductor part 181 (the intervening layer 17 in FIG. 9 may not be formed); and a solder ball heating process PR6-32 of heating the solder ball 40 to mold it into the second conductor part 182 in this order.

Furthermore, similarly to the other forming method, even in this second conductor part forming process PR6, illustrated in FIG. 9, the conductor parts formed in the preceding processes can be integrated upon heating (reflowing). That is, the method can include a heating process PR6-32 of heating the first conductor part 181 and the second conductor part 182 (solder ball 40). According to this process PR6-32, the conductor post 16 in which the metal components that constitute each of the first conductor part 181 and the second conductor part 182 are diffused into each other at the interface therebetween, firmly fusing and integrating the parts. Furthermore, according to this heating, each of the conductor parts is moderately dissolved, and in particular, the contortion of the dissolved second conductor part's 182 shape due to surface tension can be corrected by rounding it. Moreover, the position of the whole conductor post 16 can be corrected through a self-alignment effect so as to allow an axial center thereof to coincide with the conductor layer 12a. According to these actions, the wiring board 10 may have a conductor post 16 with increased reliability. The foregoing effects due to this heating process PR6-32 are especially effective where the second conductor part 182 is formed mainly of tin.

Though the heating conditions (reflowing conditions) in the heating process PR6-32 or the like are not particularly limited, the conditions in the foregoing formation of the second conductor part 182 by a photolithography method can be applied.

In the light of the above, in embodiments of manufacturing method in accordance with the present invention, there can be included not only the foregoing respective processes, including PR1 to PR6, but other processes. Furthermore, examples of other process include an intervening layer forming process PR4 of forming an electrically conductive intervening layer 17 containing nickel and gold on the surface of the first conductor part 181 prior to the second conductor forming process PR6. When including this intervening layer forming process PR4 in the second conductor forming process PR6, the second conductor part 182 is formed on the surface of the intervening layer 17. By allowing this intervening layer 17 to intervene as a primary coat between the second conductor part 182 and the first conductor part 181 prior to the formation of the second conductor part 182, and where the first conductor part 181 and the second conductor part 182 are composed of different materials, the formation of a component which lowers the joining strength of the respective constituent components that are diffused into each other in the foregoing heating process (for example, PR6-16, PR6-25, PR6-32, etc.) (for example, a component in which the respective metal elements are contained in a composition ratio of Cu to Sn of 6/5) can be effectively suppressed. As a result, wiring boards 10 may have a conductor post 16 with excellent joining strength.

The methods for forming this intervening layer 17 are not particularly limited. For example, by applying electroless nickel plating to form an electroless nickel plated layer and then applying electroless gold plating, an intervening layer 17 having a multi-layered structure in which an electroless gold plated layer is formed on the electroless nickel plated layer can be obtained.

The content of each of nickel and gold in the intervening layer 17 is not particularly limited. For example, in the case of intervening layers 17 having a multi-layered structure in which the foregoing electroless nickel plated layer and the electroless gold plated layer laminated on the electroless nickel plated layer are provided, defining the whole of the electroless nickel plated layer as 100% by mass, the content of nickel in the electroless nickel plated layer is preferably from 90 to 95% by mass. Furthermore, when the whole of the electroless gold plated layer is defined as 100% by mass, the content of gold in the electroless gold plated layer is preferably from 95 to 100% by mass. In the case where the content of each of nickel and gold falls within this range, the formation of a component which may lower the joining strength can be effectively suppressed.

Furthermore, though the thickness of the intervening layer 17 is not particularly limited, it is preferably 1 μm or more and not more than 20 μm. In the case where the thickness of the intervening layer 17 falls within this range, the formation of a component which may lower the joining strength can be more effectively suppressed. The thickness of the intervening layer 17 is more preferably 3 μm or more and not more than 15 μm, and especially preferably 6 μm or more and not more than 12 μm.

In the method according to an embodiment of the present invention, in addition to the foregoing respective processes, other process can be included. Examples of other process include a desmearing process. The desmearing process can be performed after forming the first through-hole 131, after forming the second through-hole 151, or the like. By performing this desmearing process, a residue within the through-hole can be removed.

### Embodiment

a wiring board 10 of the invention is more specifically described below with respect to the following Embodiment, but it should not be construed that the invention is limited to this Embodiment.

(1) Wiring Board 10:

A wiring substrate 10 (see FIG. 1) manufactured according to this Embodiment includes a conductor layer 12 laminated on the side of one surface of a core substrate 11, a solder resist layer 13 laminated on this conductor layer 12, and a conductor post 16 to be electrically connected to a conductor layer 12a which is disposed in a lower portion of a through-hole 131 provided in the solder resist layer 13. The core substrate 11 is composed of glass epoxy (epoxy resin containing glass fibers as a core material) having a thickness of 0.8 mm. Also, the conductor layer 12 is one obtained by patterning a copper foil having a thickness of 12 μm on one surface of the core substrate 11. Furthermore, the solder resist layer 13 has a thickness of 21 μm and contains an epoxy resin that is a thermosetting resin (the solder resist layer 13 contains 40% by mass of a filler made of silica and 60% by mass of an organic material, and furthermore, the organic material contains 80% by volume of an epoxy resin based on 100% by volume of the whole thereof). The through-hole 131 (first through hole) bored in the solder resist layer 13 has a circular shape having an aperture of 64 μm and that penetrates the back and front sides to the conductor layer 12a beneath the solder resist layer 13.

The conductor post 16 is filled up within the through-hole 131. Furthermore, a lower part of the conductor post 16 forming a columnar shape is located within the solder resist layer 13 and has a diameter of 64 mm and a height of 21 μm. Also, an upper part that forms a substantially spherical shape is located outside the solder resist layer 13 has a maximum diameter of 74 μm and a height (at the highest position) of 58 μm.

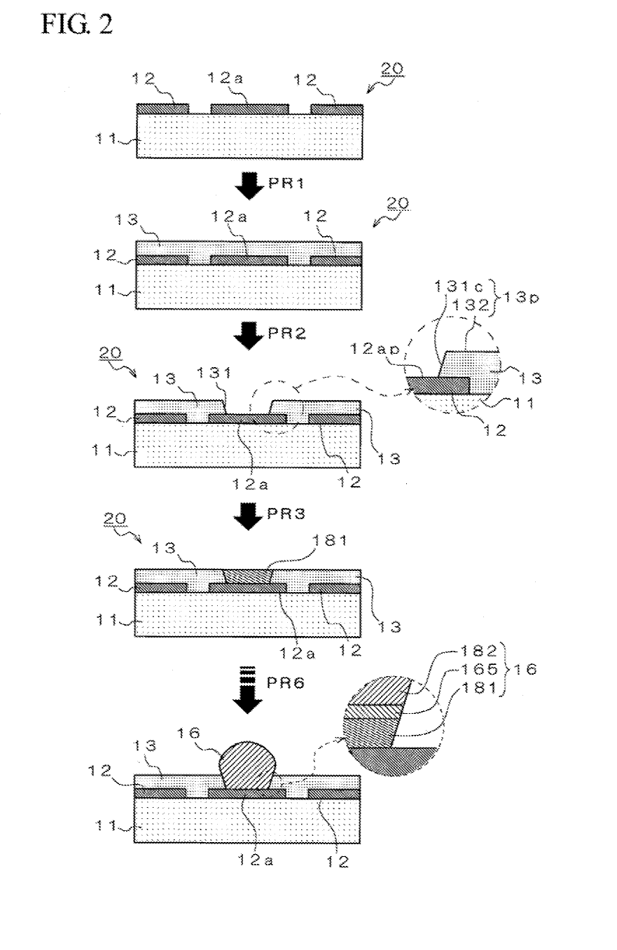

The method of manufacturing this wiring board 10 is hereunder described by reference to FIGS. 2 to 4. Incidentally, to simplify the terminology, the substrate manufactured in each of the processes and the substrates in the respective processes before becoming the wiring board 10 are all called a plain substrate 20.

A plain substrate 20 used in process PR1 (FIG. 4) includes a core substrate 11 composed of glass epoxy (epoxy resin containing glass fibers as a core material) having a thickness of 0.8 mm and a conductor layer 12 obtained by patterning a copper foil having a thickness of 12 μm as stuck on one surface of the core substrate 11.

(2) Solder Resist Layer Forming Process PR1:

A film-like solder resist layer forming composition containing an epoxy resin that is a thermosetting resin is stuck onto the surface of the side on which the conductor layer 12 of the plain substrate 20 of the foregoing (1) is provided and then is heated for curing, thereby obtaining a thermosetting resin-containing solder resist layer 13 having a thickness of 21 μm.

(3) First Through-Hole Boring Process PR2:

A laser is irradiated on the solder resist layer 13 obtained in the foregoing (2) from the surface side, thereby boring a first through-hole 131 having a diameter of 60 μm. According to this, a conductor layer 12a beneath the solder resist layer 13, for which continuity is necessary, is exposed. Also, thereafter, a desmearing treatment is performed for the purpose of removing a smear within the first through-hole 131.

(4) First Conductor Part Forming Process PR3:

The plain substrate 20 bored with the first through-hole 131 as obtained until the foregoing (3) is dipped in an electroless copper plating solution containing a nickel salt, copper sulfate, sodium hydroxide, a chelating agent, a complexing agent, and the like to perform electroless copper plating, thereby forming a first conductor part 181.

(5) Intervening Layer Forming Process PR4:

An electroless nickel plated layer is formed on the surface of the first conductor part 181 of the plain substrate 20 having the first conductor part 181 formed thereon, as obtained in the foregoing (1)-(4), by means of electroless nickel plating, and subsequently, an electroless gold plated layer is formed so as to be laminated on this electroless nickel plated layer by means of electroless gold plating. The resulting intervening layer 17 contains 93% by mass of nickel in the case of defining the whole of the electroless nickel plated layer as 100% by mass, and 100% by mass of gold in the case of defining the whole of the electroless gold plated layer as 100% by mass. It has a thickness of 3 μm.

(6) Photoresist Layer Forming Process PR6-11:

A dry film type photoresist layer 15 having a thickness of 75 μm is contact bonded onto the surface of the plain substrate 20 on which the intervening layer 17 is formed, as obtained in the foregoing (1)-(5).

(7) Second Through-Hole Boring Process PR6-12:

A second through-hole 151 which is allowed to communicate with the first through-hole 131 and which has a diameter that is the same as that of the first through-hole 131 is bored in the plain substrate 20 having the photoresist layer 15 formed thereon, obtained in the foregoing (1)-(6), by adopting a photolithography method. That is, the second through-hole 151 is formed through an exposure process, a development process, and the like. According to this, the surface of the intervening layer 17 beneath the photoresist layer 15 is exposed within the second through-hole 151. Also, thereafter, in order to remove a smear within the second through-hole 151, a desmearing treatment is performed.

(8) Second Conductor Part Plating Process PR6-13:

The plain substrate 20 having the second through-hole 151 formed therein, as obtained in the foregoing (1)-(7), is dipped in a plating solution containing, as a tin source, stannous chloride and sodium stannate to achieve electroless Sn plating. The inside of the second through-hole 151 is filled with tin plate. A second conductor part 182 is thus formed.

(9) Photoresist Layer Removing Process PR6-14:

The photoresist layer 15 is removed from the surface of the plain substrate 20 provided with the first conductor part 181 and the second conductor part 182, as obtained in the foregoing (1)-(8), by dipping in an amine based stripping solution.

(10) Heating Process PR6-16:

The plain substrate 20 as obtained the foregoing (1)-(9) is subjected to reflowing in a prescribed furnace such that the temperature reaches the melting point of tin or higher (keeping the temperature at the melting point or higher for 50 seconds), with a maximum temperature being 270° C. According to this, the first conductor part 181 and the second conductor part 182 become an integrated single conductor, and alloying (diffusion of the components constituting the intervening layer 17) is also accelerated between the first conductor part 181 and the second conductor part 182, whereby these form an integrated conductor post 16. Then, an alloy layer 165 is formed. Furthermore, the conductor post 16 approaches the central axis of the conductor layer 12a due to a self-alignment effect and is also molded into a circular form due to surface tension of the dissolved conductor metals.

### Embodiments of Methods of Use

Embodiments of the present invention can be widely utilized in the electronic part-related fields. Also, the embodied wiring boards and the like of the invention are utilized for usual wiring boards such as motherboards; wiring boards for mounting semiconductor device such as wiring boards for flip chips, wiring boards for SCPs, and wiring boards for MCPs; wiring boards for modules such as wiring boards for antenna switch modules, wiring boards for mixer modules, wiring boards for PLL modules, and wiring board for MCMs; and the like.

What is claimed is:

1. A method for manufacturing a wiring board including a conductor layer, a solder resist layer laminated on the conductor layer, and a conductor post that is electrically connected to a conductor layer which is disposed in a lower portion of a first through-hole provided in the solder resist layer, the method comprising, in the following order:
a through-hole boring process for boring the first through-hole in the solder resist layer comprising a thermosetting resin to expose the conductor layer within the first through-hole;
a first conductor part forming process for forming a first conductor part comprising copper within the first through-hole; and
a second conductor part forming process for forming a second conductor part comprising tin, copper, or a solder on the first conductor part.

2. The method for manufacturing a wiring board according to claim 1, further comprising:
an intervening layer forming process for forming an electrically conductive intervening layer comprising nickel and gold on the first conductor part; wherein
the intervening layer forming process occurs before the second conductor part forming process, and
in the second conductor part forming process, the second conductor part is formed on a surface of the intervening layer.

3. The method for manufacturing a wiring board according to claim 1, wherein the second conductor part forming process further comprises:
a printing process for printing a solder paste that forms the second conductor part.

4. The method for manufacturing a wiring board according to claim 1, wherein the second conductor part forming process further comprises:
a ball disposing process for disposing a solder ball that forms the second conductor part; and
a solder ball heating process for heating the solder ball to mold it to form the second conductor part.

5. The method for manufacturing a wiring board according to claim 1, wherein the second conductor part forming process further comprises, in the following order:
a photoresist layer forming process for forming a photoresist layer that covers a surface of a plain substrate, which includes, the conductor layer, and the solder resist layer;
a second through-hole boring process for boring in the photoresist layer a second through-hole using a photolithographical method, wherein the second through-hole is in communication with the first through-hole and has a size substantially the same as that of the first through-hole or a diameter larger than that of the first through-hole;
a second conductor part plating process for plating the second conductor part; and
a photoresist layer removing process for removing the photoresist layer.

6. The method for manufacturing a wiring board according to claim 5, wherein
the second conductor is made of tin, and
the second conductor'part forming process further comprises:
a heating process for heating the first conductor part and the second conductor part after the photoresist layer removing process.

7. A wiring board comprising:
a conductor layer;
a solder resist layer laminated on the conductor layer; and
a conductor post electrically connected to a conductor layer which is disposed in a lower portion of a through-hole provided in the solder resist layer,
wherein the solder resist layer includes a thermosetting resin.
wherein the conductor post includes a first conductor part formed within the through hole and a second conductor part formed on the first conductor part, and
wherein the first conductor part comprises copper, and the second conductor part comprises tin, copper, or a solder.
